(19) United States
(12) Patent Application Publication
(10) Pub. No.: US 2003/0168695 A1
(43) Pub. Date: Sep. 11, 2003

(54) Silicide gate process for trench MOSFET

(75) Inventors: Ritu Sodhi, Redondo Beach, CA (US); Hamilton Lu, Los Angeles, CA (US); Milton J. Boden, Redondo Beach, CA (US)

Correspondence Address: OSTROLENK FABER GERB & SOFFEN, 1180 AVENUE OF THE AMERICAS, NEW YORK, NY, 100368403

(73) Assignee: International Rectifier Corp.

(21) Appl. No.: 10/384,897

(22) Filed: Mar. 7, 2003

Related U.S. Application Data
(60) Provisional application No. 60/363,035, filed on Mar. 7, 2002.

(51) Int. Cl. H01L 29/76; H01L 29/94; H01L 31/062; H01L 31/113; H01L 31/119

(52) U.S. Cl. 257/328

(57) ABSTRACT

The tops of the conductive polysilicon gates of a trench device have a layer of a silicide such as titanium silicide which is more conductive than the polysilicon gate, thereby reducing gate resistance.

### RELATED APPLICATIONS

This application claims the benefit of U.S. Provisional Application No. 60/363,035, filed Mar. 7, 2002.

### FIELD OF THE INVENTION

This invention relates to semiconductor devices and more specifically relates to a novel structure and process for reducing the gate resistance of a MOSgated device.

### BACKGROUND OF THE INVENTION

MOSgated devices such as power MOSFETs, IGBTs, MOSgated thyristors and the like are very well known. Such devices have thin conductive polysilicon gates disposed above a gate insulation, usually an oxide, which is, disposed above invertible channel regions which are operable to turn the device on and off in response to the application of a gate control voltage to the polysilicon gate. The polysilicon gates have considerable lateral extent and are connected to a gate pad electrode, sometimes, through a gate metal bus path. The lateral resistance of the current path from the gate pad electrode to the polysilicon gate (or gates) is quite long and has a given electrical resistance.

It is desirable to reduce this resistance to improve certain characteristics, for example, speed, of the MOSgated device.

It is known in the signal transistor art (very low power memory and microprocessor chips) to use a titanium silicide layer atop the thin, flat polysilicon gates to reduce gate resistance. Thus the silicide has a lower resistance than the polysilicon gate so that the net gate resistance is reduced.

In trench type power MOSgated devices (which are rated at greater than about one watt and are much higher in power capability than signal devices), the conductive polysilicon gates are not a thin flat horizontal structure, but are a deep narrow bodies, each contained within respective parallel trenches in the silicon. Thus, the large area surfaces facing the invertible channel area are not accessible to a resistance-reducing layer as in the planar type device. It would, however, be desirable to reduce the gate resistance of a polysilicon gate in a trench-type MOSgated device.

### BRIEF DESCRIPTION OF THE INVENTION

In accordance with the invention, a highly conductive suicide is formed on top of the polysilicon gate in the trench of a trench-type MOSgated device, thus lowering the gate resistance. By “highly conductive” is meant a conductively higher than that of the usual polysilicon gate. A novel process is also provided to produce such a silicide layer. Thus, in a preferred embodiment of the invention, after the polysilicon gate has been defined in the trenches of the device, a mask is provided (or preexists) which exposes the tops of the polysilicon gate segments and covers the surrounding silicon surface. A layer of a suitable metal, for example, titanium is then sputtered atop the masked surface and is then subject to an anneal to convert the titanium over the polysilicon to titanium silicide. Other metal silicides can be used, for example; nickel silicide; cobalt silicide; molybdenum silicide and tungsten silicide. The remainder of the titanium or other metal is then stripped and the process is continued to complete the formation of the device. Thus in the final device, the gate resistance is substantially reduced.

### BRIEF DESCRIPTION OF THE DRAWINGS

FIG. 1 is a cross-section of a small portion of a wafer (or die) at an intermediate stage in the manufacture of a vertical conduction N channel MOSgated device (a power MOSFET), after the deposition of titanium metal on its upper surface.

FIG. 2 shows the structure of FIG. 1 after forming a titanium suicide atop the polysilicon gate and the formation of source and drain electrodes.

### DETAILED DESCRIPTION OF THE DRAWINGS

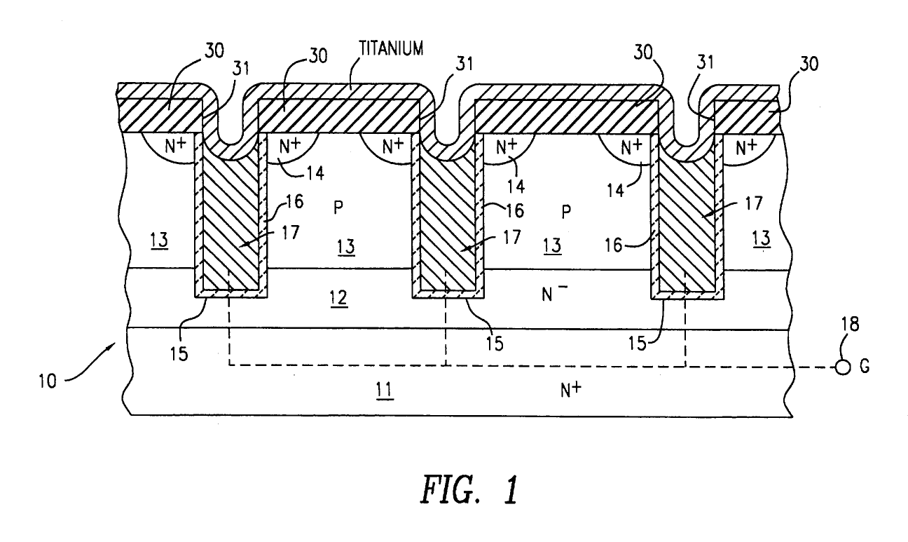

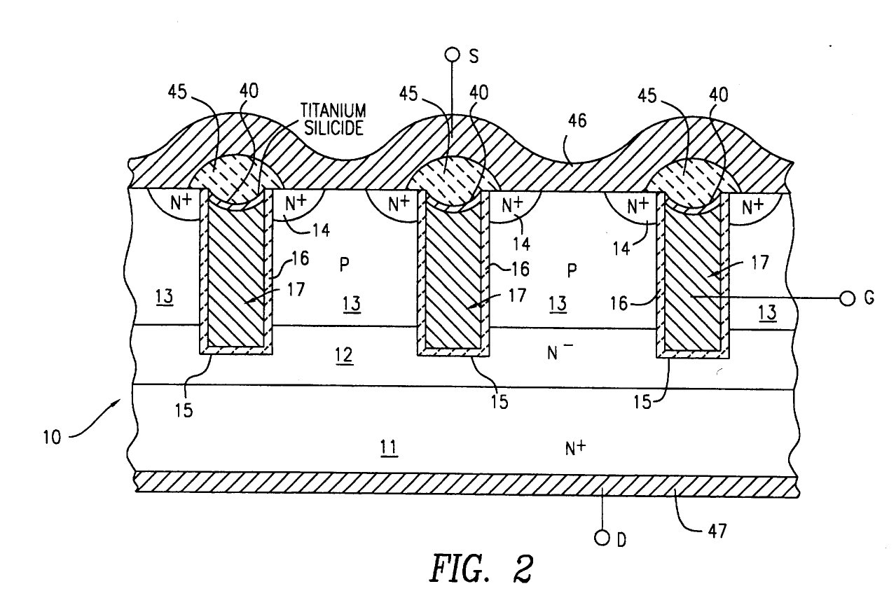

FIGS. 1 and 2 show a small portion of a silicon wafer which has an N⁺ body 11 and an epitaxially formed layer 12 atop body 11. The wafer I 0 is a standard wafer which will contain a large number of identical die which are simultaneously processed and then singulated at the end of the process. The terms wafer and die may be interchangeably used. Further, the invention is shown for an N channel device, but it will be understood that the invention can also apply to a P channel structure. Further, the invention is shown as applied to a vertical conduction power MOSFET, although the invention can be used with any trench-type MOSgated device.

In a first series of known process steps, a P type channel layer 13 is implanted and then diffused into N⁻ layer 12, and a plurality of N⁺ source regions 14 are diffused into P layer 13. A plurality of narrow, but deep trenches 15 are then etched into wafer 10 to a depth slightly less than that of layer 12. The trenches 15 may be parallel elongated stripes or may be a lattice of cellular openings of circular or other cross-section. A thin gate oxide layer 16, for example, silicon diode, is then thermally grown on the interior walls of each of the trenches.

Polysilicon gate regions 17 are then deposited in each of the trenches 15. The polysilicon regions 17 have a depth much greater than their width and are made conductive by the incorporation of an N type species, for example, phosphorus into the polysilicon as is well known. Typically, polysilicon regions 17 may be about 0.5 microns wide and about 1.5 microns deep. All of the polysilicon gates 17 are connected together (not shown) and to a common gate terminal shown as terminal 18 in FIG. 1. To this point, the process is standard and well known.

In accordance with the invention, and as shown in FIG. 1, a suitable mask layer 30 is applied over the upper surface of the wafer, and the mask layer is photolithographically processed to open windows 31 atop the polysilicon gates 17. A layer of titanium or other equitable metal, about 600 Å thick is then sputtered atop the wafer and contacts the polysilicon regions 17 through windows 31. Molybdenum or tungsten could also be used. A suitable thermal anneal process is then carried out, converting the titanium and polysilicon in contact therewith to titanium silicide regions 40 (FIG. 2), having a much higher conductivity than the polysilicon. Note that these regions 40 are suitably connected together as by coplanar runners (not shown) and to the gate terminal 18. For example, the anneal can be carried out at 625° C. for 30 seconds. Unreacted titanium is then etched away and a further anneal is continued at 750° C. for 30 seconds. The preferred resistivity of the titanium silicide layer 31 is about 1.5 ohms/square, compared to about 10 ohms/square of the polysilicon without the titanium layer. The thickness of underlying the titanium silicide layers 31 (about 1400 Å) is much less than the thickness of the remaining untreated polysilicon bodies 17.

The device fabrication is then completed as shown in FIG. 2, in the well known manner, as by the formation of LTO insulation caps 45 atop the silicide 40 and over a portion of the adjacent source regions 14, and the formation of an aluminum source electrode 46 and a trimetal drain electrode 47.

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. A trench type MOSgated device comprising a silicon substrate; a plurality of spaced trenches extending perpendicularly into said substrate; a gate oxide lining the walls of said trenches; conductive polysilicon gates filing the interior of each of said trenches; and a thin conductive silicide layer overlying and in contact with the tops of each of said polysilicon gates; each of said polysilicon gates being connected to a common gate terminal; the lateral gate resistance of said polysilicon gates being reduced by said silicide layers.

2. The device of claim 1, wherein said polysilicon gates are about 0.5 μm wide by about 1.5 μm deep.

3. The device of claim 1, wherein said silicide layer has a resistivity which is at least 3 times that of said conductive polysilicon.

4. The devices of claim 3, wherein the resistivity of said polysilicon is about 10 ohms/square and the resistivity of said silicide layer is about 1.5 ohms per square.

5. The device of claim 3, wherein said silicide is titanium silicide.

6. The device of claim 4, wherein said silicide is titanium silicide.

7. The device of claim 2, wherein said suicide layer has a resistivity which is at least 3 times that of said conductive polysilicon.

8. The devices of claim 7, wherein the resistivity of said polysilicon is about 10 ohms/square and the resistivity of said silicide layer is about 1.5 ohms per square.

9. The device of claim 8, wherein said suicide is titanium suicide.

10. The device of claim 1, wherein said silicide is about 1400 Å thick.

11. The device of claim 5, wherein said silicide is about 1400 Å thick.

12. The device of claim 9, wherein said silicide is about 1400 Å thick.
